(19) United States
(12) Patent Application Publication
(10) Pub. No.: US 2011/0013467 A1
(43) Pub. Date: Jan. 20, 2011

(54) System and Method for Reading Memory

(75) Inventor: Charles H. Moore, Sierra City, CA (US)

Correspondence Address: HENNEMAN & ASSOCIATES, PLC, 70 N. MAIN ST., THREE RIVERS, MI, 49093, US

(73) Assignee: VNS PORTFOLIO LLC, Cupertino, CA (US)

(21) Appl. No.: 12/502,682

(22) Filed: Jul. 14, 2009

(51) Int. Cl. G11C 7/00

(52) U.S. Cl. 365/190; 365/203

(57) ABSTRACT

A novel memory reading circuit includes a bit line for transmitting data bits within the memory, a plurality of storage elements for storing bits of data, and a precharge circuit coupled to the bit line for charging the bit line when the precharge circuit is in a charging state, the precharge circuit being operative to remain in the charging state at time when the storage elements assert the stored bits of data on the bit line. The memory may be a single-ended, static random access memory (“SRAM”). The SRAM circuits of the invention may be incorporated into each of a plurality of individual computers arrayed on a single die.

### BACKGROUND OF THE INVENTION

1. Field of the Invention

This invention relates generally to static memory operation, and more particularly to an improved circuit and method for reading a static memory cell, especially for application in single-chip multiprocessor arrays in embedded systems.

2. Description of the Background Art

In the art of computing, speed is a much desired quality, and the quest to create faster computers, processors, and other components is ongoing. In efforts to increase computing speed, various circuits for reading static memory have been designed.

A semiconductor static memory cell typically comprises two cross-coupled MOS inverters connected between a high voltage (Vdd) and a low voltage (Gnd), which have two stable states defined by logical high and logical low potentials at two inverter ports, Q and Q-bar (complement or inverse of Q), respectively. The logical high potential is somewhat lower than Vdd and the logical low potential is somewhat higher than Gnd, owing to finite on-state conductance of transistor channels and off-state resistance.

Prior art memory cells are commonly disposed in a two-dimensional array defined by several rows and columns. These memory cells are electrically accessed through two mutually-orthogonal arrays of bit lines and word lines running adjacent to the cells and parallel to the rows and columns. Such memory cells include two selection transistors, through which a port of the cell can be selectively connected to a bit line associated with the port, according to the potential applied to the gate electrode of an associated selection transistor. The gate electrodes of the selection transistors are connected to respective word select lines according to the row in which the cell is disposed. The Q-ports of all cells in a column connect to one bit line, and the Q-bar ports connect to a second bit line known as the complement, inverse, or Q-bar bit line. The two selection transistor gate electrodes of all cells in a row connect to a word select line and to an inverse word-select (word-bar) line, respectively. Additionally, there is a sense amplifier for each bit and bit-bar line pair, and the sense amplifier reads the state of the memory cells as they are connected one at a time to the bit-line pair. In one mode of operation, the memory cells of the array are accessed sequentially by row and simultaneously, in parallel, for a multiplicity of columns so that, for example, all bits of a multi-bit word can be read or written at the same time.

Memory devices are designed based on many competing goals and for particular applications. For example, in order to maximize the amount of memory in a given chip area, memory cells are made smaller and, to minimize the number of access lines to a given section of memory, long bit lines are used to connect to a maximum number of cells. However, small cells connected to long wires create a problem for the operating speed, speed being a desirable characteristic of memory, and thus the design of memory access circuits is necessarily a search for optimum solutions for a set of conflicting requirements, which are dependent on the application in each particular case. As an example of such optimization, for a long bit line with a large number of memory cells attached, a large and complicated memory access circuit can be provided without much impact on the per-bit chip area of the memory. However, for small memory with shorter bit lines, access circuit size becomes important because the access circuit size can quickly become too large. Furthermore, for long bit lines with a large number of small cells, differential sensing using both bit and bit-bar lines, and word and word-bar lines, is preferred in the art, to achieve good noise margin with high operating speed. However, for small memory with fewer memory cells connected to a bit line and a larger cell size, single-ended sensing using one bit line per cell can be preferable.

Precharging is a known technique used to read digital data over long lines that have significant capacitance. Precharging is commonly used to return a bit line quickly to a predetermined potential (e.g., Vdd) prior to the next read operation in the normal sequence of reading (and writing) operations on long bit lines.

Although prior art precharging circuits provide some advantages, there are still disadvantages to these circuits. For example, in the prior art, precharging is turned off prior to sensing the state of a memory cell. Turning the precharging off requires extra cycles in synchronous circuits. Similarly, turning off the precharge prior to sensing the state of a memory cell also requires extra time in asynchronous circuits, which slows down the reading operation. Moreover, the control circuitry for turning the precharge off prior to sensing the state of the memory cell can occupy valuable real estate in a crowded integrated circuit.

What is needed, therefore, is a memory reading circuit that provides faster read operations. What is also needed is a memory reading circuit that performs read operations in fewer cycles. What is also needed is a memory reading circuit that is compact in size.

### SUMMARY

The present invention overcomes the problems associated with the prior art by providing a memory device that is more compact and provides faster reads than the prior art. The invention facilitates faster reading of data by precharging the bit line and maintaining the precharge on the bit line while the memory cell is read. Because the precharge is not turned off during the read, the memory access circuitry is less complex.

According to the present invention, a memory includes a bit line for transmitting data bits within the memory, a plurality of storage elements that store data bits and that are coupled to selectively assert the stored data bits on the bit line, and a precharge circuit coupled to the bit line. The precharge circuit charges the bit line when the precharge circuit is in a charging state, and the precharge circuit remains in the charging state when the storage elements assert the data bits on the bit line. In a particular embodiment, the precharge circuit is a weak pull-up circuit and includes at least one transistor coupled in series between a voltage source and the bit line. The precharge circuit and the storage element create a voltage divider around the bit line when the precharge circuit is in its charging state and a read node of the storage element is coupled to the bit line.

The memory can also include a sense amplifier that is coupled to the bit line. The sense amplifier receives the data bits that are asserted on the bit line, inverts the data bits, and asserts the complement of the asserted data bits on a read output terminal. Optionally, both the precharge circuit may be put into a charging state and the sense amplifier may be enabled by the same bit read signal received on a bit read signal input. In a more particular embodiment, the memory includes a plurality of word lines that are each associated with at least one of the storage elements. Each of the storage elements asserts its data bit on the bit line when a select signal is asserted on an associated word line. Optionally, the bit read signal can also cause a select signal to be asserted on one or more of the word lines, such as by including a word line address in the bit read signal.

In another particular embodiment, the memory is single-ended such that each of the storage elements includes one read node and one write node. When the read node is selectively coupled to the bit line, the stored data bit is asserted on the bit line. When the write node is coupled to a write bit line, then a new data bit can be written to the storage element. The read node and the write node are logical complements such that the complementary value output by the sense amplifier is the same value that was written into the storage element via the write node.

Multiple memories of the present invention may also be associated with a plurality of processors. For example, each of a plurality of independently-functioning computers that are integrated on a single die can include a processor and a memory of the present invention. For example, the memory of the present invention can be embodied in a computer's SRAM. The computers may be arrayed such that each is connected to the other computers by dedicated data paths between two adjacent computers. The computers may communicate, as well as operate, asynchronously from one another.

A method for reading data stored in an electronic data storage element according to the present invention includes the steps of applying a continuous precharge to a bit line coupled to a data storage element, asserting a bit of data from the data storage element on the bit line, and maintaining the continuous precharge on the bit line when the storage element asserts its bit of data on the bit line. The step of applying the precharge to the bit line may include enabling the precharge circuit with a bit read signal and the step of asserting the data bit on the bit line may include enabling a word line with the same bit read signal, such as by using a word line address contained in the bit read signal. A particular method includes the steps of inverting the data bit asserted on the bit line into a bit complement, and then asserting the bit complement on a read output terminal. An inverter, used to invert the data bit, may also be enabled by the bit read signal. Another particular method includes storing a data bit in the storage element via a write node of the storage element and reading the previously stored data via a complementary read node of the storage element.

### BRIEF DESCRIPTION OF THE DRAWINGS

The present invention is described with reference to the following drawings, wherein like reference numbers denote substantially similar elements:

FIG. 1 shows a computer array according to one embodiment of the present invention;

FIG. 2 is a block diagram showing a memory device according to one embodiment of the present invention;

FIG. 3 is a schematic diagram showing portions of the memory device of FIG. 2 in greater detail;

FIG. 4 is a waveform diagram showing multiple waveforms useful in understanding the operation of the memory device shown in FIG. 2 and FIG. 3; and,

FIG. 5 is a flow chart summarizing a method for reading data stored in a memory cell according to a particular method of the present invention.

### DETAILED DESCRIPTION

The present invention overcomes the problems associated with the prior art, by providing a system and method for quickly and efficiently reading data from, for example, Static Random Access Memory (“SRAM”). In the following description, numerous specific details are set forth (e.g., specific circuit layouts) in order to provide a thorough understanding of the invention. Those skilled in the art will recognize, however, that the invention may be practiced apart from these specific details. In other instances, details of well known circuit manufacturing practices (e.g., photolithography, doping, etc.) and components have been omitted, so as not to unnecessarily obscure the present invention.

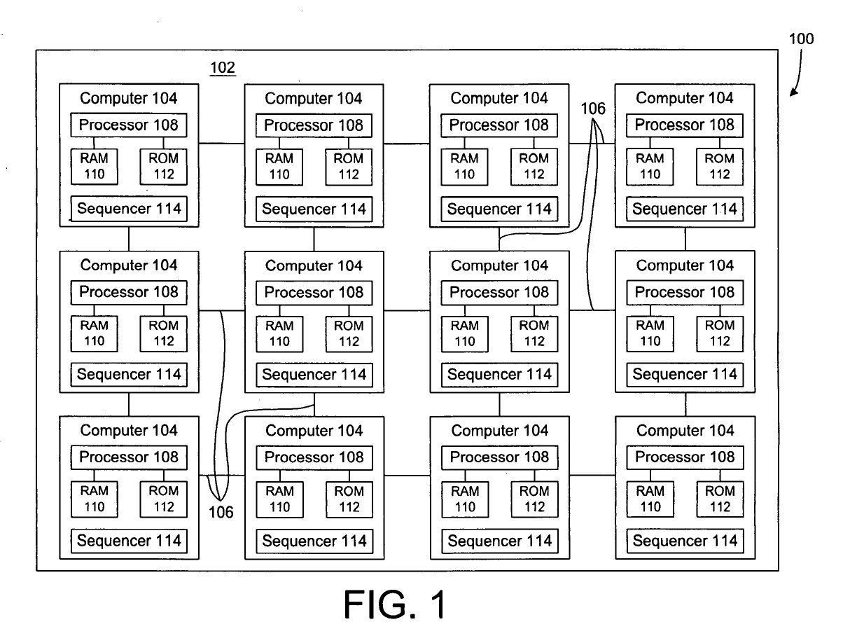

FIG. 1 shows a computer array 100 formed on a single die 102. Computer array 100 includes a plurality (twelve in this example) of computers 104 (sometimes also referred to as “cores” or “nodes” in the example of an array) interconnected by a plurality of data paths (e.g., buses) 106. According to the present invention, each of computers 102 is a generally independently-functioning computer having an individual processor 108, a RAM 110, a ROM 112, and a sequencer 114. In this example, data buses 106 are bi-directional, asynchronous, high-speed parallel, data buses, although it is within the scope of the present invention that other interconnecting means might be employed for the purpose. In the present embodiment of array 100, not only is data communication between computers 104 asynchronous, but individual computers 104 also operate in an internally-asynchronous mode due to their individual sequencers 114. In particular, each sequencer 114 provides pulses to the components of its respective computer 104 to carry out that computer's individual processes. Advantageously, because a clock signal does not have to be distributed throughout computer array 100, a great deal of power is saved. Furthermore, not having to distribute a clock signal sometimes eliminates many timing problems that could limit the size of array 100 or cause other known difficulties.

A computer array, similar to computer array 100, is described in co-pending U.S. patent application Ser. No. 11/355,495, filed Feb. 16, 2006 and entitled “Asynchronous Computer Communications,” which is incorporated by reference herein in its entirety.

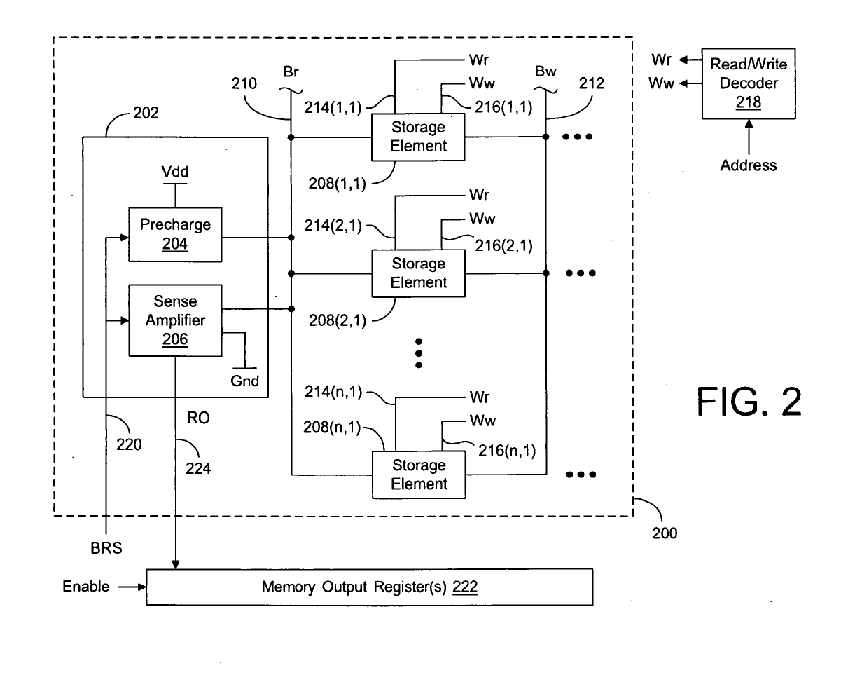

FIG. 2 is a block diagram showing a memory device 200 according to one embodiment of the present invention. Memory device 200 includes a memory reading circuit 202, which has a precharge circuit 204 and a sense amplifier 206. Memory device 200 further includes a two-dimensional array of memory cells 208(i, j) (e.g., SRAM storage elements) arranged in rows and columns, where (i) represents the row and (j) represents the column. Note that FIG. 2 shows only one column of memory cells 208 for simplicity. The memory cells 208 in a column are serviced by a read bit line 210 (labeled “Br”) and a write bit line 212 (labeled “Bw”). Each of the memory cells 208 is also connected to a read word line 214(i, j) (labeled “Wr”) and a write word line 216(i, j) (labeled “Ww”). Read word lines 214 and write word lines 216 for all memory cells 208 are uniquely addressed and enabled by a read and write decoder 218. Optionally, decoder 218 can read and write data from or to memory device by rows (or fraction of rows) of memory cells 208 instead. Memory device 200 can be employed, for example, in RAM 110 of computers 104.

In the present embodiment, memory device 200 is adapted for single-ended sensing of read data values from memory cells 208. For example, note that memory device includes only one read bit line 210 and one write bit line 212 per column of memory cells 208. A data bit value that is asserted on a write bit line 212 is latched into a memory cell 208 when decoder 218 asserts a write select signal on an associated write word line 216. Data bit values can be asserted on write bit line 212 by, for example, a memory controller (not shown). Previously-asserted data bit values are read out of a memory cell 208 onto an associated read bit line 210 when that particular memory cell 208 receives a read select signal from decoder 218 via read word line 214. As is well-known in the art, the value of the data bits stored in memory cells 208 can be represented by a logical high voltage (i.e., logical 1) or a logical low voltage (i.e., logical 0).

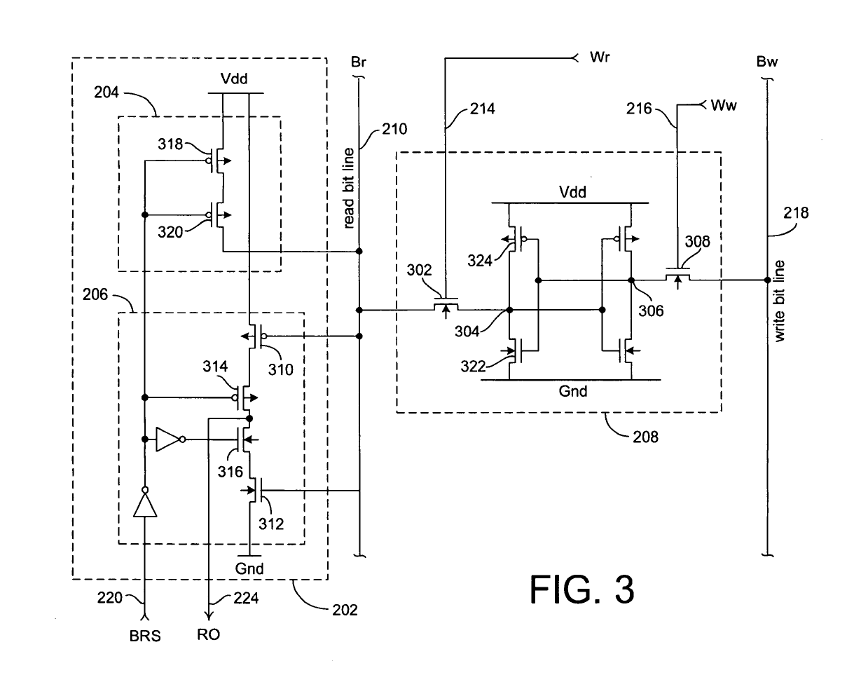

Memory reading circuit 202 facilitates faster memory accesses (among other advantages) by providing a means for precharging read bit line 210 and maintaining the precharge during the bit read process. In particular, when a bit read signal (“BRS”) is asserted on BRS line 220, precharge circuit 204 asserts a continuous precharge on read bit line 210 so that read bit line 210 charges toward a voltage, Vdd. While precharge circuit 204 is charging read bit line 210, read and write decoder 218 decodes a write address asserted on its address input and asserts a read select signal on the identified word read line 214. The associated memory cell 208 then couples a read node (FIG. 3) to read bit line 210. In the present embodiment, the BRS signal originates from a memory controller (not shown).

The sense amplifier 206, which in the present embodiment is also enabled by the BRS signal on BRS line 220, receives the signal asserted read bit line 210. Depending on the signal on read bit line 210, sense amplifier 206 asserts either a logical high or logical low value on its read output (“RO”) that is the complement of the value of the data bit stored in the read memory cell 208. The RO of the sense amplifier 206 is connected to a memory output register 222 via an RO line 224. The memory output register 222 stores the RO value for future use.

The sense amplifier 206 outputs the complement of the value stored in the memory cell 208 because the memory cell 208 has complementary input (e.g., write) and output (e.g., read) nodes. In other words, bit write line 212 may be viewed as a bit-not line. Accordingly, the values output by sense amplifier 206 are advantageously the same values that were written into the memory cells 208.

In the present embodiment, the BRS signal asserted on the BRS line 220 also includes a memory address uniquely identifying the memory cell 208 (or row or memory cells 208) where the data bit value is to be read from. Therefore, the BRS signal of the present invention advantageously enables the precharge circuit 204, the sense amplifier 206, and the decoder 218, which uses the memory address to assert a read select signal on the appropriate word read line 214.

Additionally, it should be noted that memory device 200 includes a memory reading circuit 202 for each column of memory cells 208. Furthermore, although precharge circuit 204 and sense amplifier 206 are shown as part of the same memory reading circuit 202, in actual practice it may be beneficial to provide the precharge circuits 204 separately from the sense amplifiers 206.

It should also be noted that read and write decoder 218 and memory output registers 222 are shown separated from memory device 200. For example, decoder 218 may be a part of a separate memory controller of one of computers 104. Additionally, memory output registers 222 can also be a separate component of computers 104, such as an input-output register used to communicate with another one of computers 104. As yet another option, the registers 222 and the decoder 218 may be integrated with memory device 200.

It should further be noted that although memory circuit 202 is employed in an asynchronously-operating computer as described in FIG. 1, it can also be employed in a synchronously-operating computer. Additionally, in the present embodiment, memory circuit 202 employs one precharge circuit 204 and one sense amplifier 206 per bit line. However, other configurations with precharge circuit 204 (e.g., multiple precharge circuits 204 per bit line 210, etc.) can be used.

FIG. 3 is a schematic diagram showing memory reading device 202 and one of memory cells 208 in greater detail. As shown in FIG. 3, precharge circuit 204 and sense amplifier 206 are connected to read bit line 210. Additionally, read bit line 210 is also connected to a 6-transistor, static random access memory cell 208 through a read select transistor 302. As indicated above, memory device 200 employs single-ended sensing, having only one line 210 for reading the state of a memory cell 208 and a separate line 212 for writing to a memory cell 208. In particular, read bit line 210 is used to read the state of memory cell 208 at a node 304 which is coupled to read bit line 210 through read select transistor 302. Data is written from write bit line 218 to memory cell 208 at complementary node 306 through a write select transistor 308. Having separate read and write bit lines provides a considerable advantage in faster read operations because precharge circuit 204 does not have to accommodate larger write swings on the same line when write operations alternate with read operations. Furthermore, lower noise is present on the single read bit line 210.

Sense amplifier 206 includes a p-channel transistor 310 and an n-channel transistor 312, connected in series as an inverter, through an interposed complementary pair of transistors 314 and 316. As described above, sense amplifier 206 also includes a RO signal line 224 going to memory output register 222 (FIG. 2) where the result of the read operation will be latched (stored) for further processing.

In the present embodiment, transistors 310 and 312 are asymmetrical and sized appropriately to adapt the inverter to switch its output responsive to a gate signal value (on read bit line 210) that is somewhat higher than 0.5 Vdd subject to considerations of noise margin and process variation in manufacturing. In a particular embodiment, the inverter of sense amplifier 206 switches its output responsive to a gate signal value of approximately 0.67 Vdd. In an alternative embodiment, transistors 310 and 312 can be symmetrical and sense amplifier 206 can operate around an input value of approximately 0.5 Vdd.

The transistors 314 and 316 in sense amplifier 206 form an enable gate that turns the inverter and RO line 224 connections on and off depending on the bit read select (“BRS”) signal applied to BRS line 220. As shown, a logical high asserted on line 220 will enable sense amplifier 206, whereas a logical low signal will operationally disconnect sense amplifier 206 from output line 224.

Turning now to precharge circuit 204, precharge circuit 204 includes two p-channel transistors 318 and 320 connected in series between Vdd and read bit line 210. Transistors 318 and 320 are enabled by the BRS signal asserted on BRS line 220. When the appropriate portion of BRS signal is a logical high, transistors 318 and 320 are enabled such that precharge circuit 204 charges read bit line 210 toward Vdd. As will be described in more detail below, precharge circuit 204 is a weak pull-up circuit that charges read bit line 210 toward Vdd but allows read bit line 210 to be pulled low by memory cell 208.

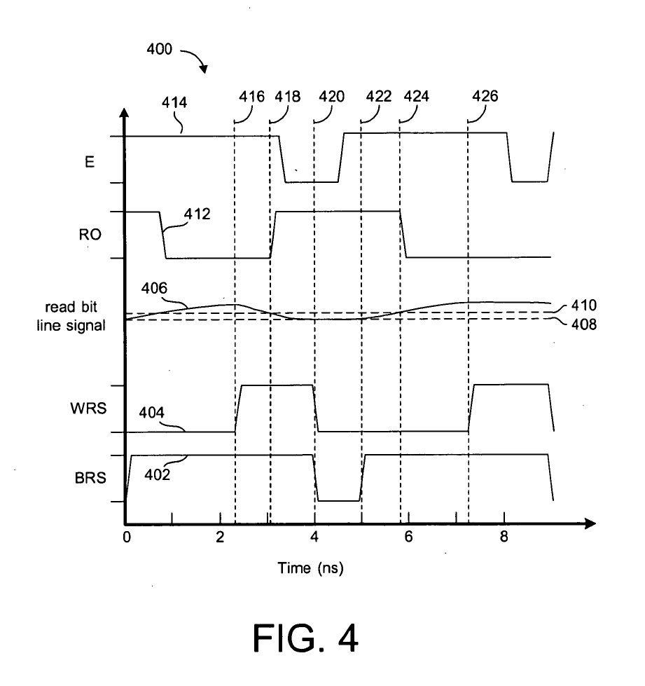

FIG. 4 shows a multiple waveform diagram 400 that is useful in understanding the operation of the memory device 200, and especially the memory reading circuit 202, shown in FIG. 2 and FIG. 3. The waveform diagram of FIG. 4 illustrates two consecutive reading operations performed by memory reading circuit 202. The waveforms illustrate first a reading operation for a logical low value and then a reading operation for a logical high value.

The bit read select signal asserted on BRS line 220 is depicted by waveform 402. A read operation begins at time 0 (chosen for convenience of description) when a logical high is asserted on BRS line 220. The logical high on BRS line 220 enables sense amplifier 206 by turning on transistors 314 and 316. The logical high BRS signal also turns on precharge circuit 204 by enabling transistors 318 and 320. In this example, transistors 318 and 320 are enabled after a time period approximately equal to the combined latency period of three inverters. In a particular embodiment, the BRS signal also simultaneously carries the address of an associated read word line 214 to a word decoding circuit such as decoder 218. Decoder 218 decodes the address and enables the corresponding read word line 214 connected to the memory cell(s) 208 that is/are to be read.

A second waveform 404 depicts the word read select (“WRS”) signal applied to read word line 214 by the decoding circuit 218. The time interval between time 0 and a time 416 before transistor 302 of memory cell 208 turns on represents the latency of the word decoding circuit 218. During this time, memory cell 208 remains disconnected from read bit line 210, precharge circuit 204 and sense amplifier 206 are connected to read bit line 210, and read bit line 210 is charging toward Vdd through transistors 318 and 320.

The charge on read bit line 210 is depicted by waveform 406. In the present embodiment, precharge circuit 204 charges read bit line 210 at a rate approximately equal to 1/(2RₚC), where Rₚ is the on-state resistance of each pull-up transistor 318 and 320 and C is the capacitance of read bit line 210. Note that the present example assumes that a logical low value was asserted on read bit line 210 in the read operation taking place before time 0 such that charging starts from a signal level 408. In the present embodiment, signal level 408 represents a voltage near the middle of the voltage span between Vdd and Gnd.

At time 416, the WRS signal on read word line 214 becomes a logical high value and transistor 302 of memory cell 208 turns on, thereby connecting node 304 of memory cell 208 to read bit line 210. When node 304 connects to read bit line 210, a voltage divider is created having resistances equal to (2Rₚ), which is attributable to the transistors 318 and 320 between Vdd and read bit line 210, and the on-state resistance (2Rₘ) attributable to transistors 302 and 322 in series from the read bit line 210 to the ground of memory cell 208. On-state resistance (2Rₘ) can also be called the pull-down resistance of read bit line 210 when a logical low value is stored at node 304 of the memory cell 208. In the present embodiment, the on-state resistances of transistors 302 and 322 are chosen to be approximately equal to each other by sizing the transistors appropriately. Furthermore, pull-up transistors 318 and 320 are also sized such that the value of Rₚ is approximately equal to the value of Rₘ.

After time 416, when transistor 302 is turned on, the signal on read bit line 210 discharges toward approximately 0.5V Vdd (recall this voltage is indicated by dashed line 408 in FIG. 4) at a rate of approximately 1/(RC). As will be described in more detail below, the voltage on read bit line 210 approaching level 408 (i.e., 0.5V Vdd), will result in sense amplifier 206 generating a digital high value read output value on RO line 224.

It should be noted that according to the present invention, and counter to conventional practice, the precharge circuit 204 is not disconnected from the read bit line 210 during the read operation. Rather, the precharge circuit 204 is a weak pull-up circuit and, therefore, does not have to be disconnected from the read bit line 210 because the bit line 210 can be pulled low by memory cell 208 in the case of a logical low value stored in memory cell 208. The present invention also provides a faster pull-down rate, as shown by waveform 406, because the pull-down resistance and the pull-up resistance act in parallel to determine the discharge time constant. Note that the weak pull-up transistors 318 and 320 exhibit resistance even when they are turned on. Because the present invention provides a faster pull-down rate, the present invention advantageously facilitates faster read operations by the memory reading circuit 202 over the prior art.

The present invention provides the additional advantage that no control circuitry is needed to disconnect the precharge circuit 204 from the bit line 206 during the read operation. Accordingly, the circuit real estate of the memory reading circuit 202 of the present invention is reduced over the prior art. Smaller physical memory size is especially important in integrated multi-computer arrays, such as the one shown in FIG. 1.

It should also be noted that, owing to the approximately 2:1 voltage divider formed at node 304 by transistors 302 and 322, the memory cell 208 is secure against accidentally changing state to a logical high value during reading of a logical low value. This is the case even when read bit line 210 and sense amplifier 206 are operating with voltages somewhat above the middle of the voltage span between Vdd and Gnd.

Returning to FIG. 4, the input switching level of the sense amplifier 206 is depicted by dashed line 410 shown on waveform 406. In particular, when read bit line signal 406 is below the signal level 410, then the read output on RO line 224 of sense amplifier 206 is a logical high value. Conversely, when the bit line signal 406 is above signal level 410, then the read output on RO line 224 is a logical low value. In FIG. 4, the output of sense amplifier 206 on RO line 224 is illustrated by waveform 412.

The RO signal transitions to a logical low value during the pull-up time interval before time 416. After time 416, the read bit line signal 406 is being pulled low by memory cell 208. At time 418, when the read bit line signal 406 crosses below the switching level 410 of sense amplifier 206, the read output RO of sense amplifier 206 transitions to a logical high value. This read output RO is the complement of the logical low value stored on node 304 of memory cell 208.

As shown in FIG. 2, RO line 224 is connected to a latch in a memory output register 222 where the RO value can be stored for further processing. A latch enable signal E transitions to a digital low value such that a latch in the memory output register 222 latches and stores the RO value on line 224. The latch enable signal E is illustrated by the waveform 414 in FIG. 4.

At a time 420, when BRS signal transitions to a logical low value, then sense amplifier 206 is operationally disconnected from RO line 224 due to the high impedance of transistors 314 and 316. The latch enable signal 414 is also changed to a logical high value a short time after time 420, which closes the latch in memory output register 222 and prevents drift or stray signal pickup on RO line 224 from being double latched into the output register 222. Turning the latch enable signal off also prepares memory reading circuit 202 for the next read operation.

A new read operation begins at a time 422 when BRS waveform 402 transitions to a logical high value. Then, the read bit line signal 406 on read bit line 210 again charges toward Vdd between times 422 and 424. At time 424, the read bit line signal 406 crosses the switching signal level 410 for sense amplifier 206 such that the RO signal on RO line 224 transitions to a logical low value. Then at time 426, responsive to a word address carried by the BRS signal to decoder 218, the enable signal on the read word line 214 transitions to a logical high value. Responsive to the logical high value asserted on read word line 214, the node 304 of memory cell 208 is coupled to read bit line 210 such that the read bit line signal 406 remains above switching signal level 410. Read bit line signal 406 remains above switching signal level 410 because precharge circuit 204 and memory cell 208 (through transistors 302 and 324) are both pulling up the voltage on read bit line 210 toward Vdd. Accordingly, sense amplifier 206 asserts (e.g., maintains in this example) a logical low value on RO line 224. Shortly after time 426, the latch enable signal 414 transitions to a logical low value to enable a latch in output register 222 to latch the logical low value for future use by an associated computer 102.

As indicated above, the RO signal on line 224 has a logical value that is the complement of the logical value asserted on node 304 of the memory cell 208. However, the nodes 304 and 306 are complements of each other, and the value of the logical signal asserted on RO line 224 is exactly what was written to node 306 of the memory cell 208 via write bit line 218.

Many alterations can be made to the present invention. For example, in one alternate embodiment, pull-up transistors 318 and 320 can be appropriately sized such that Rₚ>Rₘ. Then, with appropriate changes in the symmetry or asymmetry of the sense amplifier 206 and its switching level, read bit line 210 and sense amplifier 206 can operate around a voltage of 0.5 Vdd or lower. Furthermore, pull-up transistors with unequal on-resistances and pull-down transistors with unequal on-resistance can be employed with appropriate changes as required. As yet another example, a resistor-transistor combination could be used as an alternative weak precharge circuit 204.

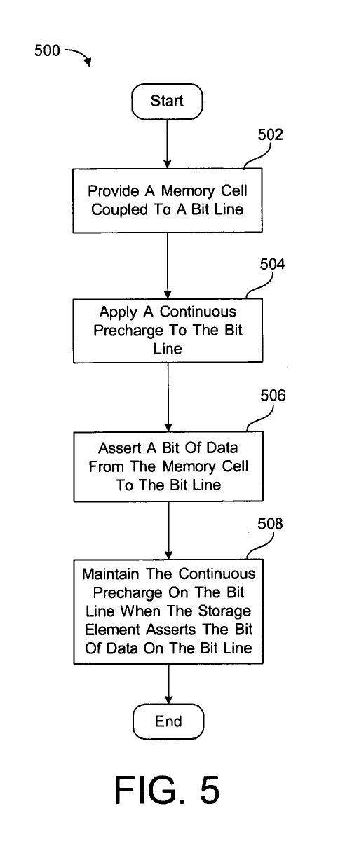

FIG. 5 is a flow chart summarizing a method 500 for reading data stored in an electronic data storage element. In a first step 502, a memory cell coupled to a bit line is provided. Next, in a second step 504, a continuous precharge is applied to the bit line. Then, in a third step 506, a signal representing a bit of data (e.g., a logical high or logical low) is asserted on the bit line from the memory cell. Finally, in a fourth step 508, the continuous precharge is maintained on the bit line while the storage element asserts the bit of data on the bit line.

The foregoing description of embodiments of the present invention has been provided for the purposes of illustration and description. It is not intended to be exhaustive or to limit the invention to the precise forms disclosed. In the interest of clarity about the invention, the illustrations and textual description of the embodiments described herein contain a number of simplifications and omissions that will be recognized by those skilled in the art. Many modifications and variations will be apparent to those skilled in the art. These variations are intended to be included in aspects of the present invention. In addition, various features and aspects of the above-described invention may be used individually or in combination. The embodiments described herein were utilized to explain the principles of the invention and its application, thereby enabling others skilled in the art to understand the invention for various embodiments and with various modifications as are suited to the particular use contemplated.

We claim:

1. A memory comprising:
a bit line for transmitting data bits within said memory;
a plurality of storage elements for storing bits of data, said storage elements coupled to selectively assert said stored bits of data on said bit line; and
a precharge circuit coupled to said bit line and operative to charge said bit line when said precharge circuit is in a charging state, said precharge circuit remaining in said charging state at a time when said storage elements assert said stored bits of data on said bit line.

2. A memory according to claim 1, wherein said precharge circuit is a weak pull-up circuit.

3. A memory according to claim 1, further comprising:
a first voltage source; and wherein
said precharge circuit includes at least one transistor coupled in series between said first voltage source and said bit line.

4. A memory according to claim 1, further comprising:
a plurality of word lines, each of said word lines associated with at least one of said storage elements;
a bit read signal input for receiving a bit read signal; and wherein
each of said storage elements asserts said bit of data on said bit line responsive to a read select signal asserted on one of said word lines associated with said storage element;
said precharge circuit charges said bit line responsive to said bit read signal being asserted on said bit read signal input; and
said bit read signal further causes said read select signal to be asserted on at least one of said word lines.

5. A memory according to claim 4, further comprising:
a sense amplifier coupled to said bit line, said sense amplifier receiving said bits of data asserted on said bit line and asserting the complements of said received bits of data on a read output terminal; and
said sense amplifier provides said complements of said bits of data on said read output terminal responsive to said bit read signal being asserted on said bit read signal input.

6. A memory according to claim 4, wherein said bit read signal includes at least one word-line address uniquely identifying at least one of said word lines.

7. A memory according to claim 1, further comprising a sense amplifier coupled to said bit line, said sense amplifier receiving said bits of data asserted on said bit line and asserting the complements of said received bits of data on a read output terminal.

8. A memory according to claim 7, further comprising:
a bit read signal input for receiving a bit read signal; and wherein
said precharge circuit charges said bit line responsive to said bit read signal being asserted on said bit read signal input; and
said sense amplifier asserts said complements of said received bits of data on said read output terminal responsive to said bit read signal being asserted on said bit read signal input.

9. A memory according to claim 1, further comprising:
a write bit line for transmitting data bits within said memory; and wherein
each of said storage elements includes a read node selectively coupled to said bit line, said read node asserting one of said bits of data on said bit line when said read node is coupled to said bit line, each of said asserted bits of data indicative of a logical value stored in said storage element; and
each of said storage elements includes a write node selectively coupled to said write bit line, said write node receiving one of said bits of data from said write bit line when said write node is coupled to said write bit line, each of said received bits of data indicative of a logical value to be stored in said storage element.

10. A memory according to claim 9, wherein said read node and said write node are logical complements.

11. A memory according to claim 10, further comprising a sense amplifier coupled to said bit line, said sense amplifier receiving said bits of data asserted on said bit line and providing the complements of said received bits of data on a read output terminal.

12. A memory according to claim 9, wherein said precharge circuit and said storage element divide the voltage on said bit line when said precharge circuit is in said charging state and said read node is coupled to said bit line.

13. A method for reading data stored in an electronic data storage element, said method comprising:
applying a continuous precharge to a bit line coupled to said data storage element;
asserting a bit of data from said data storage element on said bit line; and
maintaining said continuous precharge on said bit line when said storage element asserts said bit of data on said bit line.

14. A method according to claim 13, wherein:
said step of applying said continuous precharge to said bit line includes enabling a precharge circuit with a bit read signal such that said precharge circuit asserts a voltage on said bit line; and
said step of asserting said bit of data from said data storage element on said bit line includes further enabling a word line connected to said data storage element with said bit read signal.

15. A method according to claim 14, wherein said bit read signal includes a word line address uniquely identifying said word line.

16. A method according to claim 13, further comprising:
inverting said bit of data asserted on said bit line into a bit complement; and
asserting said bit complement on a read output terminal.

17. A method according to claim 16, wherein:
said step of applying said continuous precharge to said bit line includes enabling a precharge circuit with a bit read signal such that said precharge circuit asserts a voltage on said bit line;
said step of asserting said bit of data from said data storage element on said bit line includes enabling a word line connected to said data storage element with said bit read signal; and
said step of inverting said bit of data asserted on said bit line includes enabling an inverter connected to said bit line with said bit read signal.

18. A method according to claim 13, further comprising:
storing said bit of data in said data storage element prior to asserting said bit of data on said bit line; and wherein
said bit line is coupled to a read node of said data storage element; and
said bit of data is stored in said data storage element via a write node of said data storage element, said write node complementary to said read node.

19. An electronic device comprising:
a plurality of memory circuits and a plurality of processors, each memory circuit being associated with a respective one of said processors and including
a bit line for transmitting data bits within said memory;
a plurality of storage elements for storing bits of data, said storage elements coupled to selectively assert said stored bits of data on said bit line; and
a precharge circuit coupled to said bit line and operative to charge said bit line when said precharge circuit is in a charging state, said precharge circuit remaining in said charging state at times when said storage elements assert said stored bits of data on said bit line.

20. An electronic device according to claim 19, further comprising:
a first voltage source; and wherein
said precharge circuit includes at least one transistor coupled in series between said first voltage source and said bit line.

21. An electronic device according to claim 19, wherein:
each said memory circuit includes a plurality of word lines, each of said word lines associated with at least one of said storage elements;
each said memory circuit includes a bit read signal input for receiving a bit read signal;
each of said storage elements asserts said bit of data on said bit line responsive to a read select signal asserted on one of said word lines associated with said storage element;
said precharge circuit charges said bit line responsive to said bit read signal being asserted on said bit read signal input; and
said bit read signal further causes said read select signal to be asserted on at least one of said word lines.

22. An electronic device according to claim 21, wherein:
each said memory circuit includes a sense amplifier coupled to said bit line, said sense amplifier receiving said bits of data asserted on said bit line and asserting the complements of said received bits of data on a read output terminal; and
said sense amplifier provides said complements of said bits of data on said read output terminal responsive to said bit read signal being asserted on said bit read signal input.

23. An electronic device according to claim 21, wherein said bit read signal includes at least one word-line address uniquely identifying at least one of said word lines.

24. An electronic device according to claim 19, wherein each said memory circuit includes a sense amplifier coupled to said bit line, said sense amplifier receiving said bits of data asserted on said bit line and asserting the complements of said received bits of data on a read output terminal.

25. An electronic device according to claim 24, wherein:
each said memory circuit includes a bit read signal input for receiving a bit read signal;
said precharge circuit charges said bit line responsive to said bit read signal being asserted on said bit read signal input; and
said sense amplifier asserts said complements of said received bits of data on said read output terminal responsive to said bit read signal being asserted on said bit read signal input.

26. An electronic device according to claim 19, wherein:
each said memory circuit includes a write bit line for transmitting data bits within said memory;
each of said storage elements includes a read node selectively coupled to said bit line, said read node asserting one of said bits of data on said bit line when said read node is coupled to said bit line, each of said asserted bits of data indicative of a logical value stored in said storage element; and
each of said storage elements includes a write node selectively coupled to said write bit line, said write node receiving one of said bits of data from said write bit line when said write node is coupled to said write bit line, each of said received bits of data indicative of a logical value to be stored in said storage element.

27. An electronic device according to claim 26, wherein said read node and said write node are logical complements.

28. An electronic device according to claim 27, wherein each said memory circuit includes a sense amplifier coupled to said bit line, said sense amplifier receiving said bits of data asserted on said bit line and providing the complements of said received bits of data on a read output terminal.

29. An electronic device according to claim 26, wherein said precharge circuit and said storage element divide the voltage on said bit line when said precharge circuit is in said charging state and said read node is coupled to said bit line.

30. An electronic device according to claim 19, wherein:
said plurality of processors and said plurality of memory circuits are incorporated in a respective plurality of computers;
said plurality of computers are integrated on a single die; and
said plurality of computers are coupled to one another via a plurality of data paths, each of said data paths dedicated between two of said computers.

31. An electronic device according to claim 30, wherein each of said plurality of computers communicates asynchronously via one or more of said data paths.

32. An electronic device according to claim 31, wherein each of said plurality of computers operates asynchronously from the rest of said plurality of computers.

33. A memory comprising:
a bit line for transmitting data bits within said memory;
a plurality of storage elements for storing bits of data, said storage elements coupled to selectively assert said stored bits of data on said bit line; and
means for providing a continuous precharge on said bit line from the time before said storage element asserts a bit of data on said bit line to the time after said storage element asserts a bit of data on said bit line.
